(19) United States
(12) Patent Application Publication
(10) Pub. No.: US 2018/0198408 A1
(43) Pub. Date: Jul. 12, 2018

(54) OSCILLATOR, ELECTRONIC APPARATUS, AND VEHICLE

(71) Applicant: SEIKO EPSON CORPORATION, Tokyo (JP)

(72) Inventors: Takuya OWAKI, Shimosuwa-machi (JP); Naohisa OBATA, Minowa-machi (JP)

(73) Assignee: SEIKO EPSON CORPORATION, Tokyo (JP)

(21) Appl. No.: 15/855,460

(22) Filed: Dec. 27, 2017

(30) Foreign Application Priority Data
Jan. 12, 2017 (JP) 2017-003185

(51) Int. Cl. H03B 5/04; H03B 5/36; H05K 5/02; H05K 5/03

(52) U.S. Cl. CPC H03B 5/04; H05K 5/03; H05K 5/0217; H03B 5/36

(57) ABSTRACT

A temperature compensated oscillator, includes resonator, first case that includes base and lid and accommodates resonator, electronic component that includes oscillation and temperature compensation circuit, and second case that accommodates first case and electronic component, wherein electronic component is bonded to first case's base, and wherein in a case where temperature range of ±5° C. is changed with six minute cycle on basis of reference temperature, wander performance satisfies condition that MTIE value of 0 s<τ≤0.1 s is equal to or less than 6 ns, MTIE value of 0.1 s<τ≤1 s is equal to or less than 27 ns, MTIE value of 1 s<τ≤10 s is equal to or less than 250 ns, MTIE value of 10 s<τ≤100 s is equal to or less than 1700 ns, and MTIE value of 100 s<τ≤1000 s is equal to or less than 6332 ns when observation time is set to τ.

### BACKGROUND

### 1. Technical Field

The present invention relates to an oscillator, an electronic apparatus, and a vehicle.

### 2. Related Art

A Temperature Compensated Crystal Oscillator (TCXO) includes a quartz crystal vibrator and an Integrated Circuit (IC) for oscillating the quartz crystal vibrator, and the IC compensates for (temperature compensation) a deviation (frequency deviation) of an oscillation frequency of the quartz crystal vibrator from a desired frequency (nominal frequency) in a predetermined temperature range, thereby obtaining high frequency accuracy. Such a temperature compensated crystal oscillator (TCXO) is disclosed in, for example, JP-A-2014-53663.

In addition, the temperature compensated crystal oscillator has high frequency stability, and thus is used in communication apparatuses requiring high performance and high reliability, and the like.

A frequency signal (oscillation signal) which is output from an oscillator has phase fluctuations. Among the phase fluctuations of the frequency signal, a fluctuation at a frequency lower than 10 Hz is referred to as wander. Wander performance in a constant temperature state is specified in ITU-T Recommendation G.813.

However, in practical use, it is difficult to operate the oscillator under an environment where a temperature is maintained constant. For example, even when the oscillator is based on ITU-T Recommendation G.813, there is a possibility that the oscillator cannot sufficiently exhibit its performance under a severe temperature environment such as a case where the oscillator is used in a car navigation device or meters for vehicles or a case where the oscillator is embedded in a device in which a temperature suddenly changes due to the operation of a fan or the like.

### SUMMARY

An advantage of some aspects of the invention is to provide an oscillator which is also usable in an electronic apparatus or a vehicle requiring high frequency stability even under a severe temperature environment. Another advantage of some aspects of the invention is to provide an electronic apparatus and a vehicle which include the oscillator.

The invention can be implemented as the following forms or application examples.

### APPLICATION EXAMPLE 1

An oscillator according to this application example is a temperature compensated oscillator, the oscillator including a resonator, a first case that includes a base and a lid and accommodates the resonator, an electronic component that includes an oscillation circuit and a temperature compensation circuit, and a second case that includes the first case and the electronic component, in which the electronic component is bonded to the base of the first case, and in which in a case where a temperature range of ±5° C. is changed with a cycle of six minutes on the basis of a reference temperature, wander performance satisfies a condition that an MTIE value of 0 s<τ≤0.1 s is equal to or less than 6 ns, an MTIE value of 0.1 s<τ≤1 s is equal to or less than 27 ns, an MTIE value of 1 s<τ≤10 s is equal to or less than 250 ns, an MTIE value of 10 s<τ≤100 s is equal to or less than 1700 ns, and an MTIE value of 100 s<τ≤1000 s is equal to or less than 6332 ns when an observation time is set to τ.

Various oscillation circuits such as a Pierce oscillation circuit, an inverter type oscillation circuit, a Colpitts oscillation circuit, a Hartley oscillation circuit may be configured by the resonator and the oscillation circuit.

In the oscillator according to this application example, in a case where the temperature range of ±5° C. is changed with a cycle of six minutes on the basis of the reference temperature, the wander performance satisfies the condition that the MTIE value of 0 s<τ≤0.1 s is equal to or less than 6 ns, the MTIE value of 0.1 s<τ≤1 s is equal to or less than 27 ns, the MTIE value of 1 s<τ≤10 s is equal to or less than 250 ns, the MTIE value of 10 s<τ≤100 s is equal to or less than 1700 ns, and the MTIE value of 100 s<τ≤1000 s is equal to or less than 6332 ns when the observation time is set to T, and the oscillator has excellent wander performance even under an environment where the temperature fluctuates. For this reason, the oscillator according to this application example is also usable in an electronic apparatus or a vehicle requiring high frequency stability even under a severe temperature environment.

### APPLICATION EXAMPLE 2

In the oscillator according to the application example, in a case where a temperature is maintained constant at the reference temperature, the wander performance may satisfy a condition that an MTIE value of 0.1 s<τ≤1 s is equal to or less than 15 ns, an MTIE value of 1 s<τ≤10 s is equal to or less than 23 ns, an MTIE value of 10 s<τ≤100 s is equal to or less than 100 ns, and an MTIE value of 100 s<τ≤1000 s is equal to or less than 700 ns.

In the oscillator according to this application example, in a case where the temperature is maintained constant at the reference temperature, the wander performance may satisfy a condition that the MTIE value of 0.1 s<τ≤1 s is equal to or less than 15 ns, the MTIE value of 1 s<τ≤10 s is equal to or less than 23 ns, the MTIE value of 10 s<τ≤100 s is equal to or less than 100 ns, and the MTIE value of 100 s<τ≤1000 s is equal to or less than 700 ns, and the oscillator has more excellent wander performance than that of a temperature compensated crystal oscillator of the related art. For this reason, the oscillator according to this application example is also usable in an electronic apparatus or a vehicle requiring high frequency stability.

### APPLICATION EXAMPLE 3

In the oscillator according to the application example, the lid of the first case may be bonded to the second case.

In the oscillator according to this application example, the lid of the first case is bonded to the second case, and thus it is possible to bond the electronic component to the outer bottom surface of the base of the first case. For this reason, it is possible to reduce a difference in temperature between the resonator and the electronic component.

### APPLICATION EXAMPLE 4

In the oscillator according to the application example, the second case may include a base and a lid, and the resonator may be positioned between the lid of the first case and the lid of the second case.

In the oscillator according to this application example, it is possible to cause the lid of the first case and the lid of the second case to function as shields for shielding noise from the outside and to reduce the influence of noise to the resonator.

### APPLICATION EXAMPLE 5

In the oscillator according to the application example, a terminal electrically connected to the resonator may be provided on a surface of the base of the first case which is bonded to the electronic component.

In the oscillator according to this application example, the terminal electrically connected to the resonator can be separated from the surface which is bonded to the first case of the second case, and to reduce the influence of noise from the outside.

### APPLICATION EXAMPLE 6

In the oscillator according to the application example, a space in the second case may be a vacuum.

In the oscillator according to this application example, the space in the second case is a vacuum, and thus it is possible to reduce the influence of a temperature fluctuation outside the second case on the electronic component and the resonator.

### APPLICATION EXAMPLE 7

An oscillator according to this application example is a temperature compensated oscillator, the oscillator including a resonator, a first case that includes a base and a lid and accommodates the resonator, an electronic component that includes an oscillation circuit and a temperature compensation circuit, and a second case that accommodates the first case and the electronic component, in which the electronic component is bonded to the base of the first case, and in which in a case where a temperature is maintained constant at a reference temperature, wander performance satisfies a condition that an MTIE value of 0.1 s<τ≤1 s is equal to or less than 15 ns, an MTIE value of 1 s<τ≤10 s is equal to or less than 23 ns, an MTIE value of 10 s<τ≤100 s is equal to or less than 100 ns, and an MTIE value of 100 s<τ≤1000 s is equal to or less than 700 ns.

In the oscillator according to this application example, in a case where the temperature is maintained constant at the reference temperature, the wander performance satisfies the condition that the MTIE value of 0.1 s<τ≤1 s is equal to or less than 15 ns, the MTIE value of 1 s<τ≤10 s is equal to or less than 23 ns, the MTIE value of 10 s<τ≤100 s is equal to or less than 100 ns, and the MTIE value of 100 s<τ≤1000 s is equal to or less than 700 ns, and the oscillator has more excellent wander performance than that of a temperature compensated crystal oscillator of the related art. For this reason, the oscillator according to this application example is also usable in an electronic apparatus or a vehicle requiring high frequency stability.

### APPLICATION EXAMPLE 8

An electronic apparatus according to this application example includes any one of the oscillators described above.

According to this application example, it is possible to realize the electronic apparatus including the oscillator having high frequency stability even under a severe temperature environment.

### APPLICATION EXAMPLE 9

A vehicle according to this application example includes any one of the oscillators described above.

According to this application example, it is possible to realize the vehicle including the oscillator having high frequency stability even under a severe temperature environment.

### BRIEF DESCRIPTION OF THE DRAWINGS

The invention will be described with reference to the accompanying drawings, wherein like numbers reference like elements.

FIG. 1 is a schematic perspective view showing an oscillator according to this exemplary embodiment.

FIG. 2 is a schematic cross-sectional view showing the oscillator according to this exemplary embodiment.

FIG. 3 is a schematic plan view showing the oscillator according to this exemplary embodiment.

FIG. 4 is a schematic bottom view showing the oscillator according to this exemplary embodiment.

FIG. 5 is a schematic plan view showing a base of a package of the oscillator according to this exemplary embodiment.

FIG. 6 is a functional block diagram of the oscillator according to this exemplary embodiment.

FIG. 7 is a flow chart showing an example of a procedure of a method of manufacturing the oscillator according to this exemplary embodiment.

FIG. 8 is a diagram showing a measurement system for evaluating wander performance.

FIG. 9 is a schematic cross-sectional view showing a configuration of a comparative sample.

FIG. 10 is a graph showing a temperature profile within a chamber.

FIG. 11 is a graph showing evaluation results of wander performance of the oscillator according to this exemplary embodiment.

FIG. 12 is a graph showing evaluation results of wander performance of the oscillator according to this exemplary embodiment.

FIG. 13 is a schematic plan view showing of a base of a package of an oscillator according to a first modification example.

FIG. 14 is a schematic cross-sectional view showing an oscillator according to a third modification example.

FIG. 15 is a functional block diagram showing an example of a configuration of an electronic apparatus according to this exemplary embodiment.

FIG. 16 is a diagram showing an example of the appearance of the electronic apparatus according to this exemplary embodiment.

FIG. 17 is a diagram showing an example of a vehicle according to this exemplary embodiment.

### DESCRIPTION OF EXEMPLARY EMBODIMENTS

Hereinafter, a preferred exemplary embodiment of the invention will be described in detail with reference to the accompanying drawings. Meanwhile, this exemplary embodiment described below is not unduly limited to the contents of the invention described in the appended claims. In addition, all configurations described below are not necessarily essential configurational requirements of the invention.

### 1. Oscillator

### 1.1. Configuration of Oscillator

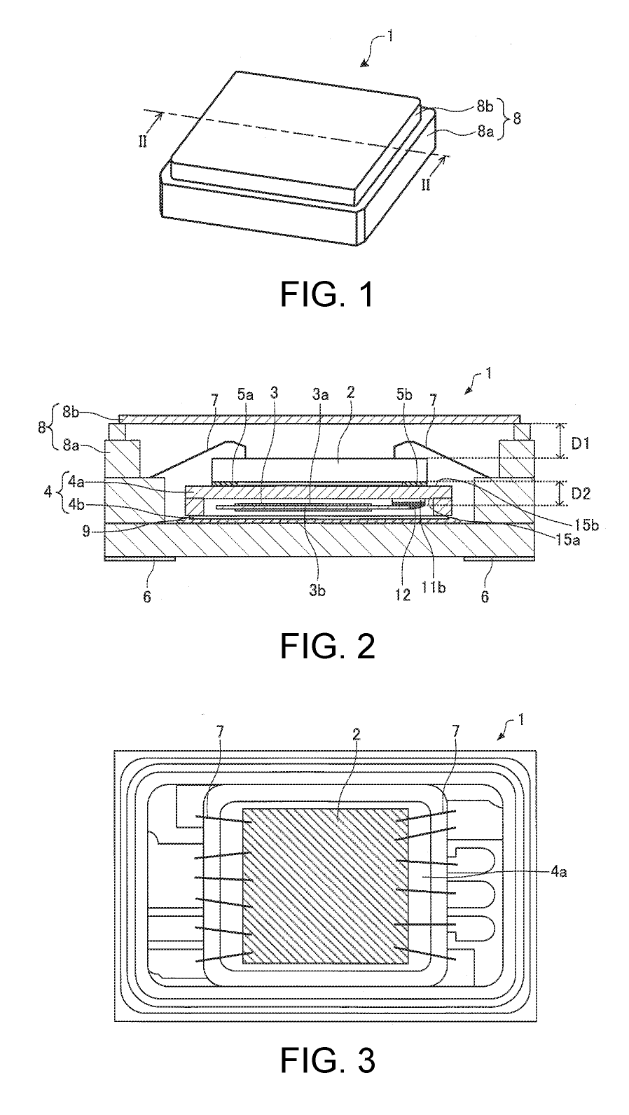

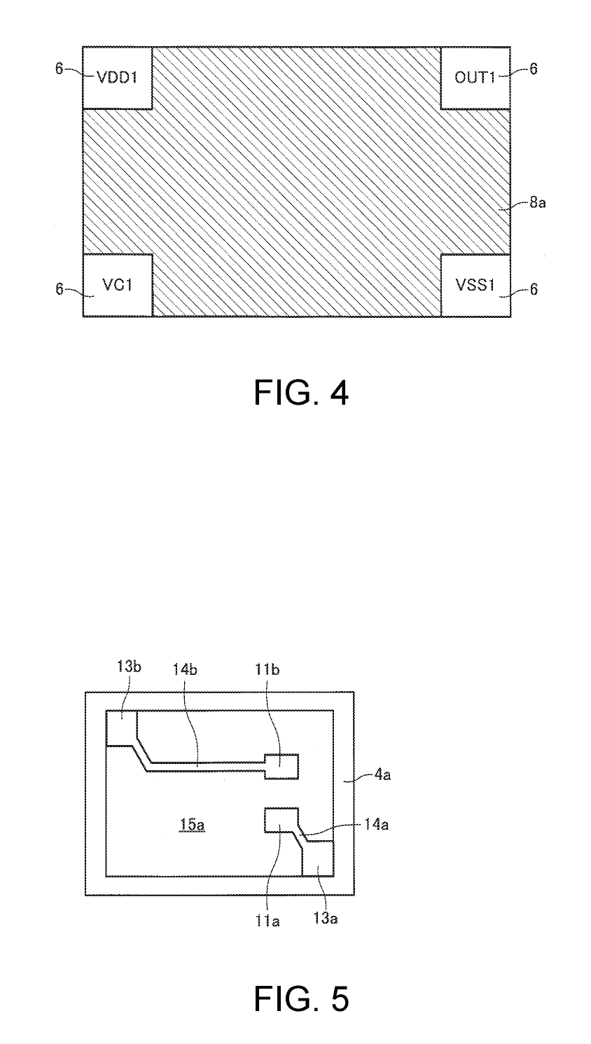

FIGS. 1 to 4 are schematic diagrams showing an example of the structure of an oscillator 1 according to this exemplary embodiment. FIG. 1 is a perspective view of the oscillator 1. FIG. 2 is a cross-sectional view taken along line II-II of FIG. 1. FIG. 3 is a top view of the oscillator 1. FIG. 4 is a bottom view of the oscillator 1. However, in FIG. 3, a lid 8b is not shown for convenience of description.

As illustrated in FIGS. 1 to 4, the oscillator 1 is configured to include an Integrated Circuit (IC) 2 which is an electronic component, a resonator (vibrator element) 3, a package (first case) 4, and a package (second case) 8.

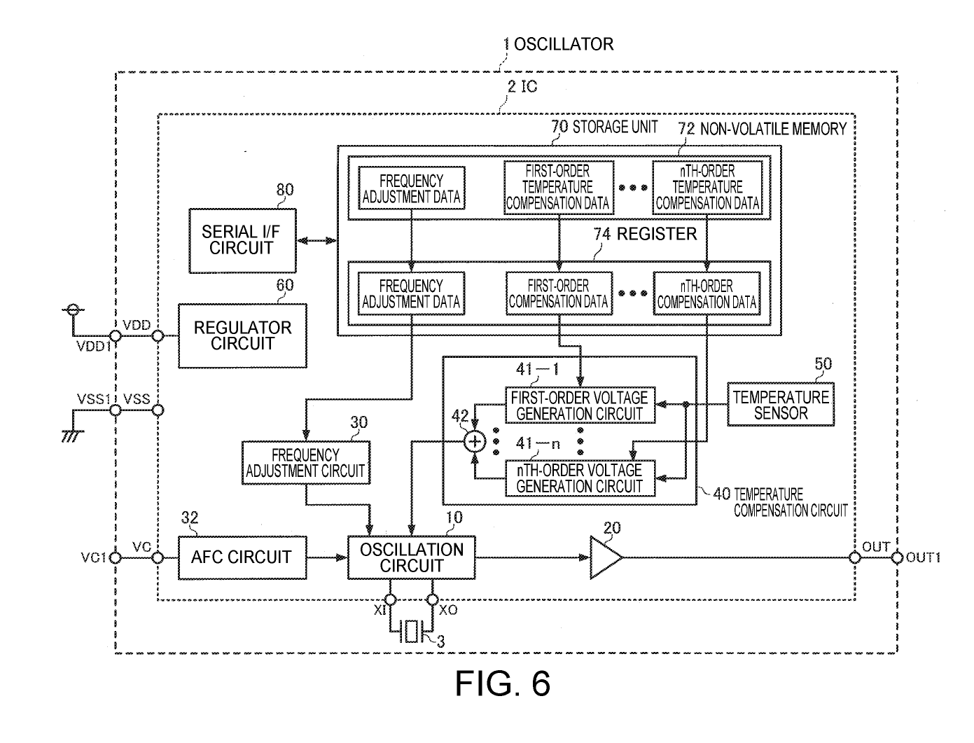

The integrated circuit (IC) 2 is accommodated in the package 8. As described later, the integrated circuit (IC) 2 is configured to include an oscillation circuit 10 and a temperature compensation circuit 40 (see FIG. 6).

Examples of the resonator 3 to be used may include a quartz crystal resonator, a Surface Acoustic Wave (SAW) resonance element, other piezoelectric resonators or Micro Electro Mechanical Systems (MEMS) resonators, and the like. Examples of a substrate material of the resonator 3 to be used may include a piezoelectric material such as piezoelectric single crystal, for example, quartz, lithium tantalate, and lithium niobate, piezoelectric ceramics, for example, lead zirconate titanate, a silicon semiconductor material, and the like. As excitation means of the resonator 3, excitation means based on a piezoelectric effect may be used, or electrostatic driving based on a Coulomb force may be used.

The resonator 3 includes a metal excitation electrode 3a and a metal excitation electrode 3b on the surface side and the rear surface side, and oscillates at a desired frequency (frequency required for the oscillator 1) based on the mass of the resonator 3 including the excitation electrode 3a and the excitation electrode 3b.

The package 4 includes a base (package base) 4a and a lid (cover) 4b that seals the base 4a. The package 4 accommodates the resonator 3. Specifically, the base 4a is provided with a recessed portion, and the recessed portion is covered with the lid 4b, so that the resonator 3 is accommodated. A space in which the package 4 accommodates the resonator 3 is an inert gas atmosphere such as a nitrogen gas.

Although the material of the base 4a is not particularly limited, various ceramics such as aluminum oxide can be used. Although the material of the lid 4b is not particularly limited, the material is a metal such as nickel (Ni), cobalt (Co), or an iron alloy (for example, Kovar). In addition, the lid 4b may be a lid obtained by coating a plate-shaped member with such a metal.

A metal body for sealing may be provided between the base 4a and the lid 4b. The metal body may be a so-called seam ring constituted by, for example, a cobalt alloy for seam sealing, or may be configured by directly disposing a metal film on a ceramic material constituting the base 4a.

FIG. 5 is a schematic plan view showing the base 4a of the package 4.

As illustrated in FIG. 5, electrode pads 11a and 11b, electrode pads 13a and 13b, and leading wirings 14a and 14b are provided on a first surface (bottom surface of the recessed portion of the base 4a) 15a of the base 4a. Meanwhile, the base 4a includes a plate-shaped base body having the electrode pads 11a and 11b disposed therein, and a frame surrounding the first surface 15a.

The electrode pads 11a and 11b are electrically connected to the two excitation electrodes 3a and 3b of the resonator 3, respectively. The resonator 3 is bonded (adhered) to the electrode pads 11a and 11b by using a connection member 12 such as a conductive adhesive.

The electrode pads 13a and 13b are electrically connected to the two external terminals 5a and 5b (see FIG. 2) of the package 4, respectively.

The leading wiring 14a electrically connects the electrode pad 11a and the electrode pad 13a to each other. The leading wiring 14b electrically connects the electrode pad 11b and the electrode pad 13b to each other.

As illustrated in FIG. 2, the package 4 is bonded (adhered) to the package 8. Specifically, the lid 4b of the package 4 is bonded to the base 8a of the package 8. That is, the lid 4b is positioned on the bottom surface side of the recessed portion of the base 8a, and the base 4a is positioned on the lid 8b side. For this reason, in the example illustrated in FIG. 2, the lid 4b is positioned on the lower side, and the base 4a is positioned on the upper side. The lid 4b and the base 8a are bonded (adhered) to each other by using the connection member 9 such as a conductive adhesive or an insulating adhesive. Meanwhile, a method of bonding the lid 4b and the base 8a to each other is not particularly limited.

Meanwhile, at least a portion of a surface of the lid 4b which is in contact with the connection member 9 may be in a rough state (roughened surface). In this case, a bonding state to the connection member 9 is improved, and thus impact resistance and heat exchanging performance are improved. The roughened surface has irregularities by, for example, laser beam machining, and is more rough than, for example, a surface on an accommodation space side not having been subjected to such machining. In addition, the lid 4b may be warped so as to be projected toward the resonator 3 side. Thereby, it is possible to increase a gap between the lid 4b and the base 8a and to decrease heat exchanging capacity between the lid 4b and the base 8a.

In this exemplary embodiment, the lid 4b of the package 4 is bonded to the base 8a of the package 8 as described above, and thus the resonator 3 is positioned between the lid 4b and the lid 8b as illustrated in FIG. 2. The resonator 3 is positioned in a region where the lid 4b and the lid 8b overlap each other when seen in a plan view (when seen from above the oscillator 1, when seen from a direction perpendicular to the bottom surface of the base 8a).

The external terminals 5a and 5b electrically connected to the resonator 3 are provided on the second surface 15b of the base 4a. The two external terminals 5a and 5b of the package 4 are electrically connected to two terminals (an XO terminal and an XI terminal of FIG. 6 to be described later) of the integrated circuit (IC) 2, respectively.

The integrated circuit (IC) 2 is bonded to the base 4a of the package 4. Specifically, the integrated circuit (IC) 2 is bonded to the second surface (a surface on a side opposite to the first surface 15a, the outer bottom surface of the base 4a) 15b of the base 4a. The integrated circuit (IC) 2 may be bonded (adhered) to the base 4a by using an adhesive or silver paste, or may be bonded thereto by using a metal bump or the like.

As illustrated in FIG. 3, the integrated circuit (IC) 2 and the package 4 (resonator 3) overlap each other when seen in a plan view, and the integrated circuit (IC) 2 is directly attached to the base 4a. In this manner, the integrated circuit (IC) 2 is bonded to the base 4a, and thus the integrated circuit (IC) 2 and the resonator 3 can be disposed so as to be close to each other. Thereby, heat generated by the integrated circuit (IC) 2 is transmitted to the resonator 3 in a short period of time, and thus it is possible to reduce a difference in temperature between the integrated circuit (IC) 2 and the resonator 3.

For example, regarding the integrated circuit (IC) 2, at least a portion of a surface which is in contact with an adhesive member, not shown in the drawing, for bonding to the package 4 may be in a rough state (roughened surface). In this case, a bonding state to the adhesive member is improved, and thus impact resistance and heat exchanging performance are improved. Meanwhile, the roughened surface may have striped irregularities formed by, for example, grinding. In addition, the second surface 15b of the base 4a may be wrapped so as to be recessed. When a recess due to such wrapping is positioned so as to overlap the integrated circuit (IC) 2, the adhesive member is easily gathered in the recess. Thereby, since a sufficient amount of adhesive member can be disposed between the integrated circuit (IC) 2 and the base 4a, adhesion between both the integrated circuit and the base is improved, and heat exchanging performance between the integrated circuit (IC) 2 and the base 4a, that is, the integrated circuit (IC) 2 and the resonator 3 is improved.

The package 8 includes the base (package base) 8a and the lid (cover) 8b that seals the base 8a. The package 8 accommodates the package 4 accommodating the resonator 3 and the integrated circuit (IC) 2 in the same space. Specifically, the base 8a is provided with a recessed portion, and the recessed portion is covered with the lid 8b, so that the integrated circuit (IC) 2 and the package 4 are accommodated. A space where the package 8 accommodates the integrated circuit (IC) 2 and the package 4 is an inert gas atmosphere such as a nitrogen gas.

A space is provided between the inner surface of the package 8 and the package 4. In the example shown in the drawing, the inner wall surface (inner surface) of the base 8a and the package 4 are not in contact with each other, and a space (gap) is provided therebetween. In addition, the lid 8b and the package 4 are not in contact with each other, and a space (gap) is provided therebetween.

A space is provided between the inner surface of the package 8 and the integrated circuit (IC) 2. In the example shown in the drawing, the inner surface of the base 8a and the integrated circuit (IC) 2 are not in contact with each other, and a space (gap) is provided therebetween. In addition, the lid 8b and the integrated circuit (IC) 2 are not in contact with each other, and a space (gap) is provided therebetween.

Although the material of the base 8a is not particularly limited, various ceramics such as aluminum oxide can be used. The material of the lid 8b is, for example, a metal. The material of the lid 8b may be the same as, for example, the material of the lid 4b. The lid 8b in this exemplary embodiment has a plate shape, and the area of the lid 8b is smaller than the area of a gap shape having a recess. For this reason, it is easy to fend off wind from the side of the package, and thus it is possible to suppress a fluctuation in temperature due to outside air. Meanwhile, a sealing body is used for the bonding between the base 8a made of ceramic and the lid 8b. The sealing body is a metal sealing body including a material such as a cobalt alloy or Au, or is a non-metal sealing body such as glass or a resin.

In the oscillator 1, a distance D1 between the lid 8b of the package 8 and the integrated circuit (IC) 2 is larger than a distance D2 between the integrated circuit (IC) 2 and the resonator 3. In the example shown in the drawing, the distance D1 is a distance between the lower surface of the lid 8b and the upper surface of the integrated circuit (IC) 2, and the distance D2 is a distance between the lower surface of the integrated circuit (IC) 2 and the upper surface of the resonator 3. In this manner, the integrated circuit (IC) 2 is brought closer to the resonator 3 than the lid 8b, and thus it is possible to reduce a difference in temperature between the integrated circuit (IC) 2 and the resonator 3.

A wiring, not shown in the drawing, which is electrically connected to each external terminal 6 is provided inside the base 8a or on the surface of the recessed portion, and each wiring and each terminal of the integrated circuit (IC) 2 are bonded to each other through a bonding wire 7 such as gold.

As illustrated in FIG. 4, four external terminals 6 of an external terminal VDD1 which is a power terminal, an external terminal VSS1 which is a ground terminal, an external terminal VC1 which is a terminal to which a signal for controlling frequency is input, and an external terminal OUT1 which is an output terminal are provided on the rear surface of the base 8a. A power supply voltage is supplied to the external terminal VDD1, and the external terminal VSS1 is grounded.

FIG. 6 is a functional block diagram of the oscillator 1. As illustrated in FIG. 6, the oscillator 1 is an oscillator including the resonator 3 and the integrated circuit (IC) 2 for oscillating the resonator 3.

The integrated circuit (IC) 2 is provided with a VDD terminal which is a power terminal, a VSS terminal which is a ground terminal, an OUT terminal which is an output terminal, a VC terminal which is a terminal to which a signal for controlling frequency is input, and an XI terminal and an XO terminal which are terminals for connection to the resonator 3. The VDD terminal, the VSS terminal, the OUT terminal, and the VC terminal are exposed to the surface of the integrated circuit (IC) 2, and are respectively connected to the external terminals VDD1, VSS1, OUT1, and VC1 provided in the package 8. In addition, the XI terminal is connected to one end (one terminal) of the resonator 3, and the XO terminal is connected to the other end (the other terminal) of the resonator 3.

In this exemplary embodiment, the integrated circuit (IC) 2 is configured to include the oscillation circuit 10, an output circuit 20, a frequency adjustment circuit 30, an Automatic Frequency Control (AFC) circuit 32, a temperature compensation circuit 40, a temperature sensor 50, a regulator circuit 60, a storage unit 70, and a serial interface (I/F) circuit 80. Meanwhile, the integrated circuit (IC) 2 may be configured such that a portion of the components is omitted or changed or other components are added.

The regulator circuit 60 generates a constant voltage serving as a power supply voltage or a reference voltage of some or all of the oscillation circuit 10, the frequency adjustment circuit 30, the AFC circuit 32, the temperature compensation circuit 40, and the output circuit 20 on the basis of a power supply voltage VDD (positive voltage) which is supplied from the VDD terminal.

The storage unit 70 includes a non-volatile memory 72 and a register 74, and is configured such that reading or writing with respect to the non-volatile memory 72 or the register 74 can be performed through the serial interface circuit 80 from the external terminal. In this exemplary embodiment, there are only four terminals VDD, VSS, OUT, and VC of the integrated circuit (IC) 2 which are connected to the external terminal of the oscillator 1, and thus the serial interface circuit 80 receives a clock signal which is input from the VC terminal and a data signal which is input from the OUT terminal, for example, when the voltage of the VDD terminal is higher than a threshold value, and performs the reading or writing of data on the non-volatile memory 72 or the register 74.

The non-volatile memory 72 is a storage unit for storing various pieces of control data. The non-volatile memory may be any of various rewritable non-volatile memories such as an Electrically Erasable Programmable Read-Only Memory (EEPROM) or a flash memory, or may be any of various non-rewritable non-volatile memories such as a One-Time Programmable Read Only Memory (one-time PROM).

The non-volatile memory 72 stores frequency adjustment data for controlling the frequency adjustment circuit 30, and temperature compensation data (first-order compensation data, . . . , and nth-order compensation data) for controlling the temperature compensation circuit 40. Further, the non-volatile memory 72 also stores pieces of data (not shown) for respectively controlling the output circuit 20 and the AFC circuit 32.

The frequency adjustment data is data for adjusting the frequency of the oscillator 1, and can be finely adjusted so that the frequency of the oscillator 1 approximates a desired frequency, by rewriting the frequency adjustment data in a case where the frequency of the oscillator 1 deviates from the desired frequency.

The temperature compensation data (the first-order compensation data, . . . , and the nth-order compensation data) is data for correcting a frequency temperature characteristic of the oscillator 1, the temperature compensation data being calculated in a temperature compensation adjustment process of the oscillator 1. For example, the temperature compensation data may be first to nth-order coefficient values based on respective order components of the frequency temperature characteristic of the resonator 3. Here, as the maximum-order n of the temperature compensation data, a value capable of canceling the frequency temperature characteristic of the resonator 3 and correcting the influence of a temperature characteristic of the integrated circuit (IC) 2 is selected. For example, n may be an integer value larger than a main order of the frequency temperature characteristic of the resonator 3. For example, when the resonator 3 is an AT cut quartz crystal resonator, the frequency temperature characteristic represents a cubic curve, and the main order is 3. Accordingly, an integer value (for example, 5 or 6) which is larger than may be selected as “n”. Meanwhile, the temperature compensation data may include compensation data of all of the first-order to nth-order, or may include only compensation data of some of the first-order to nth-order.

The pieces of data stored in the non-volatile memory 72 are transmitted from the non-volatile memory 72 to the register 74 when the integrated circuit (IC) 2 is turned on (when the voltage of the VDD terminal rises from 0 V to a desired voltage), and are held in the register 74. The frequency adjustment data held in the register 74 is input to the frequency adjustment circuit 30, the temperature compensation data (the first-order compensation data, . . . , and the nth-order compensation data) which is held in the register 74 is input to the temperature compensation circuit 40, and the pieces of data for control which are held in the register 74 are also input to the output circuit 20 and the AFC circuit 32.

In a case where the non-volatile memory 72 is a non-rewritable memory, each data is directly written in each bit of the register 74 holding each data transmitted from the non-volatile memory 72 and is adjusted and selected so that the oscillator 1 satisfies a desired characteristic through the serial interface circuit 80 from the external terminal during the examination of the oscillator 1, and the adjusted and selected pieces of data are finally written in the non-volatile memory 72. In addition, in a case where the non-volatile memory 72 is a rewritable memory, the pieces of data may be written in the non-volatile memory 72 through the serial interface circuit 80 from the external terminal during the examination of the oscillator 1. However, since the writing in the non-volatile memory 72 generally takes time, each data may be written in each bit of the register 74 through the serial interface circuit 80 from the external terminal during the examination of the oscillator 1 in order to shorten an examination time, and the adjusted and selected data may be finally written in the non-volatile memory 72.

The oscillation circuit 10 amplifies an output signal of the resonator 3 to feed back the amplified output signal to the resonator 3, thereby oscillating the resonator 3 and outputting an oscillation signal based on the oscillation of the resonator 3. For example, a current at an oscillation stage of the oscillation circuit 10 may be controlled on the basis of the control data held in the register 74.

The frequency adjustment circuit 30 generates a voltage based on the frequency adjustment data held in the register 74 and applies the generated voltage to one end of a variable capacitance element (not shown) functioning as a load capacity of the oscillation circuit 10. Thereby, control (fine adjustment) is performed so that an oscillation frequency (reference frequency) of the oscillation circuit 10 under conditions in which a predetermined temperature (for example, 25° C.) is set and the voltage of the VC terminal is set to a predetermined voltage (for example, VDD/2) is set to substantially a desired frequency.

The AFC circuit 32 generates a voltage based on the voltage of the VC terminal and applies the generated voltage to one end of the variable capacitance element (not shown) functioning as the load capacity of the oscillation circuit 10. Thereby, an oscillation frequency (oscillation frequency of the resonator 3) of the oscillation circuit 10 is controlled on the basis of the voltage value of the VC terminal. For example, a gain of the AFC circuit 32 may be controlled on the basis of the control data held in the register 74.

The temperature sensor 50 is a temperature-sensitive element that outputs a signal (for example, a voltage based on a temperature) based on the ambient temperature. The temperature sensor 50 may be a positive polarity sensor in which an output voltage becomes higher as a temperature becomes higher, or may be a negative polarity sensor in which an output voltage becomes lower as a temperature becomes lower. Meanwhile, the temperature sensor 50 to be preferably used may be a temperature sensor in which an output voltage changes linearly as much as possible with respect to a change in temperature in a desired temperature range in which the operation of the oscillator 1 is guaranteed.

The temperature compensation circuit 40 receives an input of an output signal from the temperature sensor 50, generates a voltage (temperature compensation voltage) for compensating for the frequency temperature characteristic of the resonator 3, and applies the generated voltage to one end of the variable capacitance element (not shown) functioning as the load capacity of the oscillation circuit 10. Thereby, the oscillation frequency of the oscillation circuit 10 is controlled to substantially a constant frequency, irrespective of temperature. In this exemplary embodiment, the temperature compensation circuit 40 is configured to include first-order to nth-order voltage generation circuits 41-1 to 41-n and an addition circuit 42.

An output signal from the temperature sensor 50 is input to each of the first-order voltage generation circuit 41-1 to the nth-order voltage generation circuit 41-n, and a first-order compensation voltage to an nth-order compensation voltage for respectively compensating for a first-order component to an nth-order component of the frequency temperature characteristic are generated on the basis of the first-order compensation data to the nth-order compensation data which are held in the register 74.

The addition circuit 42 adds up the first-order compensation voltage to the nth-order compensation voltage which are respectively generated by the first-order voltage generation circuit 41-1 to the nth-order voltage generation circuit 41-n and outputs the added-up voltage. The output voltage of the addition circuit 42 serves as an output voltage (temperature compensation voltage) of the temperature compensation circuit 40.

The output circuit 20 receives an input of an oscillation signal which is output by the oscillation circuit 10, generates an oscillation signal to be output to the outside, and outputs the generated oscillation signal to the outside through the OUT terminal. For example, a frequency division ratio and an output level of the oscillation signal in the output circuit 20 may be controlled on the basis of the control data held in the register 74. An output frequency range of the oscillator 1 is, for example, equal to or greater than 10 MHz and equal to or less than 800 MHz.

The oscillator 1 configured in this manner functions as a voltage controlled temperature compensated oscillator (Voltage Controlled Temperature Compensated Crystal Oscillator (VC-TCXO) when the resonator 3 is a quartz crystal resonator) which outputs an oscillation signal having a constant frequency based on the voltage of the external terminal VC1, irrespective of a temperature, in a desired temperature range.

### 1.2. Method of Manufacturing Oscillator

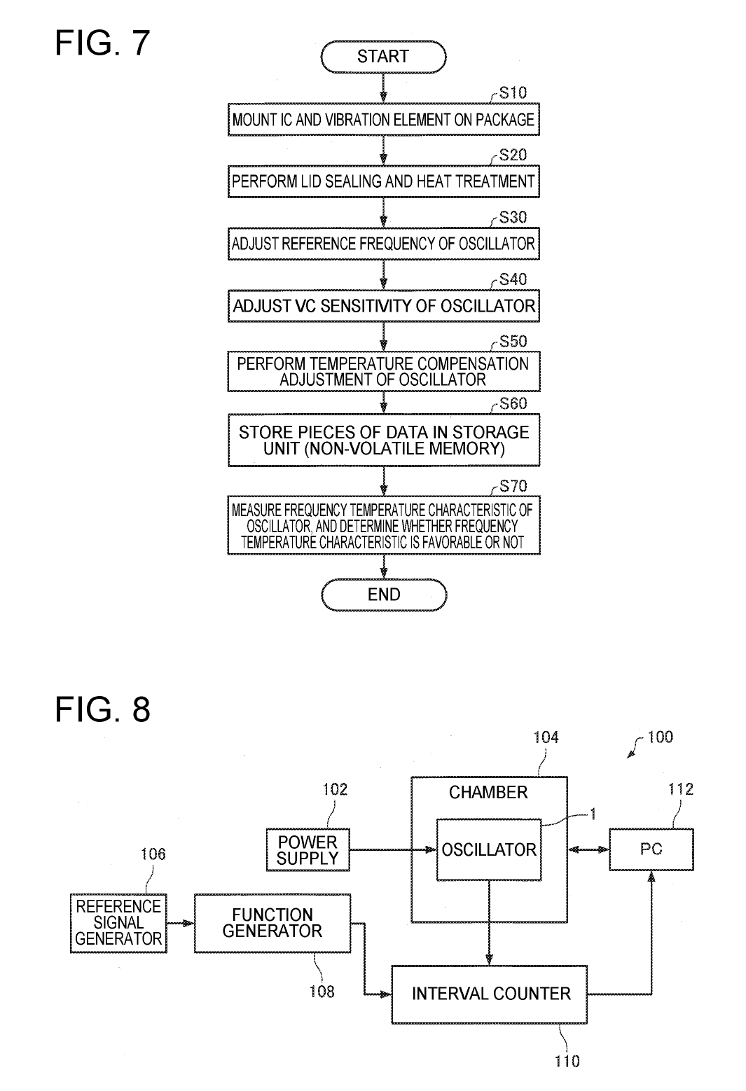

FIG. 7 is a flow chart showing an example of a procedure of a method of manufacturing the oscillator 1 according to this exemplary embodiment. Some of steps S10 to S70 in FIG. 7 may be omitted or changed, or other steps may be added. In addition, the order of the steps may be appropriately changed in a possible range.

In the example of FIG. 7, first, the integrated circuit (IC) 2 and the resonator 3 (package 4 accommodating the resonator 3) are mounted in the package 8 (base 8a) (S10). The integrated circuit (IC) 2 and the external terminals 5a and 5b of the package 4 are connected to each other by step S10, and the integrated circuit (IC) 2 and the resonator 3 are electrically connected to each other when the integrated circuit (IC) 2 is turned on.

Next, the base 8a is sealed by the lid 8b, and heat treatment is performed thereon, thereby bonding the lid 8b to the base 8a (S20). The assembling of the oscillator 1 is completed by step S20.

Next, a reference frequency (frequency at a reference temperature T0 (for example, 25° C.)) of the oscillator 1 is adjusted (S30). In step S30, a frequency is measured by oscillating the oscillator 1 at the reference temperature T0, and frequency adjustment data is determined so that a frequency deviation approximates to zero.

Next, a VC sensitivity of the oscillator 1 is adjusted (S40). In step S40, a frequency is measured by oscillating the oscillator 1 in a state where a predetermined voltage (for example, 0 V or VDD) is applied to the external terminal VC1 at the reference temperature T0, and adjustment data of the AFC circuit 32 is determined so that a desired VC sensitivity is obtained.

Next, temperature compensation adjustment of the oscillator 1 is performed (S50). In this temperature compensation adjustment process S50, the frequency of the oscillator 1 is measured at a plurality of temperatures in a desired temperature range (for example, equal to or higher than −40° C. and equal to or lower than 85° C.), and temperature compensation data (the first-order compensation data, . . . , and the nth-order compensation data) for correcting the frequency temperature characteristic of the oscillator 1 is generated on the basis of measurement results. Specifically, a calculation program for the temperature compensation data approximates the frequency temperature characteristic (including a frequency temperature characteristic of the resonator 3 and a temperature characteristic of the integrated circuit (IC) 2) of the oscillator 1 by an nth-order expression with a temperature (output voltage of the temperature sensor 50) as a variable by using the measurement results of the frequency at the plurality of temperatures, and generates the temperature compensation data (the first-order compensation data, . . . , and the nth-order compensation data) based on the approximate expression. For example, the calculation program for the temperature compensation data sets a frequency deviation at the reference temperature T0 to zero, and generates the temperature compensation data (the first-order compensation data, . . . , and the nth-order compensation data) for reducing the width of the frequency deviation in a desired temperature range.

Next, the pieces of data obtained in steps S30, S40, and S50 are stored in the non-volatile memory 72 of the storage unit 70 (S60).

Finally, the frequency temperature characteristic of the oscillator 1 is measured, and it is determined whether the frequency temperature characteristic is favorable or not (S70). In step S70, the frequency of the oscillator 1 is measured while gradually changing a temperature, and it is evaluated whether or not a frequency deviation is within a predetermined range in a desired temperature range (for example, equal to or higher than −40° C. and equal to or lower than 85° C.). It is determined that the frequency temperature characteristic is favorable when the frequency deviation is within the predetermined range, and it is determined that the frequency temperature characteristic is not favorable when the frequency deviation is not within the predetermined range.

### 1.3. Wander Performance of Oscillator

Wander refers to a fluctuation at a frequency lower than 10 Hz among phase fluctuations of a frequency signal (oscillation signal) which is output from an oscillator. Wander performance is specified on the basis of a maximum time interval error (MTIE). The MTIE refers to a peak-to-peak maximum value of the amount of phase fluctuation with respect to a reference clock within a certain observation time τ when an observation result of the amount of phase fluctuation is sectioned at intervals of the observation time τ. That is, the peak-to-peak maximum value of the amount of phase fluctuation with respect to the reference clock within the observation time τ is set to be an MTIE value at the observation time τ.

FIG. 8 is a diagram showing a measurement system 100 for evaluating the wander performance of the oscillator 1 (for measuring an MTIE value).

As illustrated in FIG. 8, the measurement system 100 includes the oscillator 1, a power supply 102, a chamber 104, a reference signal generator 106, a function generator 108, an interval counter 110, and a personal computer (PC) 112.

A configuration of the oscillator 1 used for this evaluation is as described in the above-described “1.1. Configuration of Oscillator” (see FIGS. 1 to 4). Meanwhile, a space for accommodating the resonator 3 of the package 4 and a space for accommodating the integrated circuit (IC) 2 of the package 8 and the package 4 are nitrogen gas atmospheres. In addition, the resonator 3 is a quartz crystal resonator. A power supply voltage Vcc=3.3V is supplied to the oscillator 1 from the power supply 102. An output frequency (nominal frequency) of the oscillator 1 is set to 19.2 MHz. The oscillator 1 has a CMOS output format, and a capacity load thereof is set to 15 pF.

The oscillator 1 is accommodated in the chamber 104 of which the temperature can be controlled. The temperature in the chamber 104 is controlled by the PC 112.

In the measurement system 100, a reference signal (reference clock) is obtained by generating a frequency signal of 19.2 MHz which is the same as the output frequency of the oscillator 1 by the function generator 108 from a frequency signal of 10 MHz which is output by the reference signal generator 106.

A signal to be measured (frequency signal of the oscillator 1) and a reference signal are input to the interval counter 110. In the interval counter 110, the amount of phase fluctuation of the signal to be measured with respect to the reference signal is measured, and an MTIE value is calculated in the PC 112 from results of the measurement.

Meanwhile, as a comparative example, a temperature compensated crystal oscillator of the related art (comparative sample C1) is prepared, and evaluation of wander performance is similarly performed on the comparative sample C1.

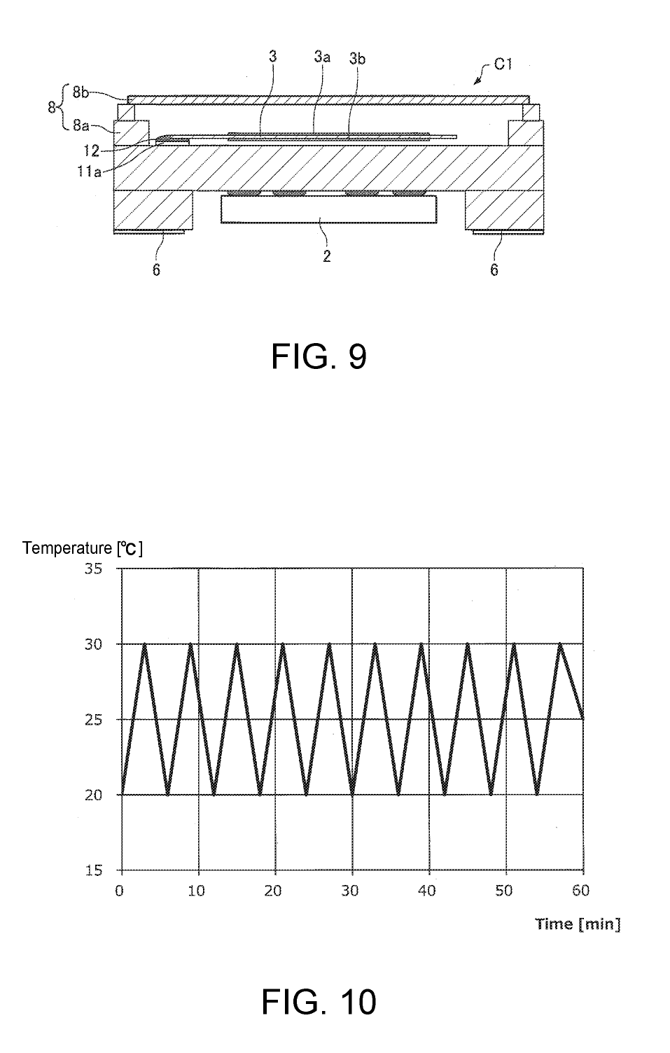

FIG. 9 is a schematic cross-sectional view showing a configuration of the comparative sample C1.

In the comparative sample C1, the base 8a has an H-shaped structure in which each of two principal planes is provided with a recessed portion, as illustrated in FIG. 9. In the comparative sample C1, the resonator 3 is accommodated in the recessed portion provided in one principal plane of the base 8a, and the integrated circuit (IC) 2 is accommodated in the recessed portion provided in the other principal plane. Meanwhile, the other configurations of the comparative sample C1 are the same as those of the oscillator 1.

(1) Wander Performance when Temperature is Changed

First, wander performance of the oscillator 1 when changing the temperature in the chamber 104 was evaluated using the measurement system 100 illustrated in FIG. 8.

FIG. 10 is a graph showing a temperature profile within the chamber 104. Meanwhile, the horizontal axis in the graph illustrated in FIG. 10 represents a time (minute), and the vertical axis represents a temperature in the chamber 104.

Here, in the measurement system 100, an MTIE value of the oscillator 1 was measured while changing the temperature in the chamber 104 in the temperature profile illustrated in FIG. 10. Specifically, as illustrated in FIG. 10, regarding the temperature in the chamber 104, a temperature range of ±5° C. was changed with a cycle of six minutes on the basis of a reference temperature T0 (25° C.). More specifically, a process of linearly raising the temperature of the chamber 104 from 20° C. to 30° C. for three minutes and then linearly lowering the temperature from 30° C. to 20° C. for three minutes was repeated.

Meanwhile, the same measurement was performed on the comparative sample C1.

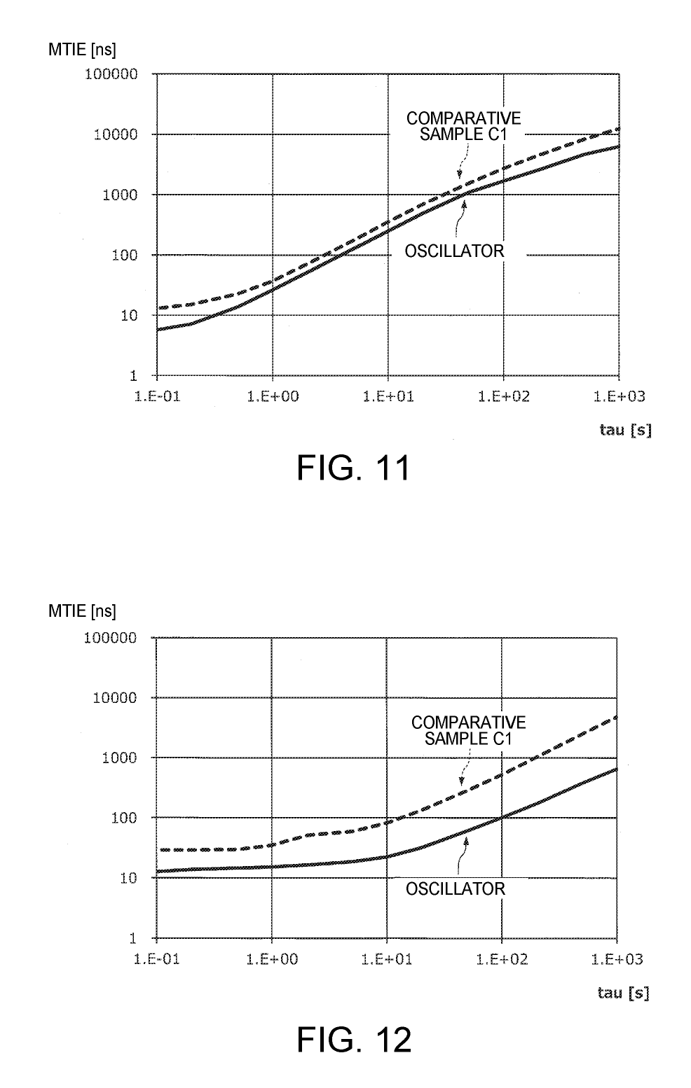

FIG. 11 is a graph showing evaluation results (MTIE value measurement results) of wander performance of the oscillator 1 and the comparative sample C1 in a case where a temperature range of ±5° C. was changed with a cycle of six minutes on the basis of a reference temperature T0 (25° C.). The horizontal axis in the graph illustrated in FIG. 11 represents an observation time τ (second), and the vertical axis represents an MTIE value (10⁻⁹ seconds).

The following Table 1 is a table showing MTIE values of the oscillator 1 and the comparative sample C1 at τ=0.1 s (seconds), τ=1 s, τ=10 s, τ=100 s, and τ=1000 s.

TABLE 1

| | MTIE Value [ns] of | MTIE Value [ns] of |
|---|---|---|
| τ[s] | Oscillator 1 | Comparative Sample C1 |
| 0.1 | 6 | 13 |
| 1 | 27 | 37 |
| 10 | 246 | 351 |
| 100 | 1678 | 2704 |
| 1000 | 6332 | 12520 |

As shown in FIG. 11 and Table 1, in the oscillator 1, in a case where a temperature range of ±5° C. is changed with a cycle of six minutes on the basis of a reference temperature, wander performance satisfies a condition that an MTIE value of 0 s<τ≤0.1 s is equal to or less than 6 ns (nanoseconds), an MTIE value of 0.1 s<τ≤1 s is equal to or less than 27 ns, an MTIE value of 1 s<τ≤10 s is equal to or less than 250 ns, an MTIE value of 10 s<τ≤100 s is equal to or less than 1700 ns, and an MTIE value of 100 s<τ≤1000 s is equal to or less than 6400 ns. More accurately, in the oscillator 1, in a case where the temperature range of ±5° C. is changed with a cycle of six minutes on the basis of the reference temperature, wander performance satisfies a condition that an MTIE value of 0 s<τ≤0.1 s is equal to or less than 6 ns (nanoseconds), an MTIE value of 0.1 s<τ≤1 s is equal to or less than 27 ns, an MTIE value of 1 s<τ≤10 s is equal to or less than 250 ns, an MTIE value of 10 s<τ≤100 s is equal to or less than 1700 ns, and an MTIE value of 100 s<τ≤1000 s is equal to or less than 6332 ns. In this manner, the oscillator 1 has more excellent wander performance than that of the comparative sample C1.

(2) Wander Performance in Case where Temperature is Maintained Constant at Reference Temperature

Next, wander performance of the oscillator 1 in a case where the reference temperature T0 in the chamber 104 was maintained constant at a chamber 104 was evaluated using the measurement system 100 illustrated in FIG. 8.

Here, in the measurement system 100, an MTIE value of the oscillator 1 was measured by maintaining the temperature in the chamber 104 constant at the reference temperature T0 (25° C.)

Meanwhile, the same measurement was performed on the comparative sample C1.

FIG. 12 is a graph showing evaluation results (MTIE value measurement results) of wander performance of the oscillator 1 and the comparative sample C1 in a case where the temperature in the chamber 104 is maintained constant at a reference temperature T0 (25° C.). The horizontal axis in the graph illustrated in FIG. 12 represents an observation time τ (second), and the vertical axis represents an MTIE value (10⁻⁹ seconds).

The following Table 2 is a table showing MTIE values of the oscillator 1 and the comparative sample C1 at τ=0.1 s, τ=1 s, τ=10 s, τ=100 s, and τ=1000 s.

TABLE 2

| | MTIE Value [ns] of | MTIE Value [ns] of |
|---|---|---|
| τ[s] | Oscillator 1 | Comparative Sample C1 |
| 0.1 | 13 | 29 |
| 1 | 15 | 35 |
| 10 | 23 | 83 |
| 100 | 100 | 520 |
| 1000 | 656 | 4825 |

As shown in FIG. 12 and Table 2, in the oscillator 1, in a case where the temperature is maintained constant at the reference temperature T0 (25° C.), wander performance satisfies a condition that an MTIE value of 0.1 s<τ≤1 s is equal to or less than 15 ns, an MTIE value of 1 s<τ≤10 s is equal to or less than 23 ns, an MTIE value of 10 s<τ≤100 s is equal to or less than 100 ns, and an MTIE value of 100 s<τ≤1000 s is equal to or less than 700 ns. In this manner, the oscillator 1 has more excellent wander performance than that of the comparative sample C1 even when taking a condition that the temperature is constant.

The oscillator 1 according to this exemplary embodiment has, for example, the following features.

In a case where the oscillator 1 changes a temperature range of ±5° C. with a cycle of six minutes on the basis of the reference temperature T0, wander performance satisfies a condition that an MTIE value of 0 s<τ≤0.1 s is equal to or less than 6 ns, an MTIE value of 0.1 s<τ≤1 s is equal to or less than 27 ns, an MTIE value of 1 s<τ≤10 s is equal to or less than 250 ns, an MTIE value of 10 s<τ≤100 s is equal to or less than 1700 ns, and an MTIE value of 100 s<τ≤1000 s is equal to or less than 6332 ns.

Here, wander performance in a constant temperature state is specified in ITU-T Recommendation G.813. In the oscillator 1, wander performance in a case of changing a temperature satisfies the wander performance in a constant temperature state, which is specified in ITU-T Recommendation G.813, in a range of 0 s<τ≤100 s. In addition, even in a range of 100 s<τ≤1000, performance which is inferior but close to the specified wander performance is obtained. In this manner, the oscillator 1 has excellent wander performance even under an environment where a temperature fluctuates. For this reason, the oscillator 1 is also usable in an electronic apparatus or a vehicle requiring high frequency stability even under a severe temperature environment.

In the oscillator 1, in a case where the temperature is maintained constant at a reference temperature T0, wander performance satisfies a condition that an MTIE value of 0.1 s<τ≤1 s is equal to or less than 15 ns, an MTIE value of 1 s<τ≤10 s is equal to or less than 23 ns, an MTIE value of 10 s<τ≤100 s is equal to or less than 100 ns, and an MTIE value of 100 s<τ≤1000 s is equal to or less than 700 ns. The wander performance of the oscillator 1 sufficiently satisfies the wander performance specified in ITU-T Recommendation G.813, and thus the oscillator 1 has excellent wander performance.

In addition, in the oscillator 1, a difference between wander performance in a case of changing a temperature and wander performance in a case of maintaining a constant temperature is smaller than that in a temperature compensated crystal oscillator (comparative sample C1) of the related art. That is, it can be said that the oscillator 1 has a small deterioration of wander performance even under a severe temperature environment.

In this manner, the oscillator 1 has more excellent wander performance even under a severe temperature environment than that in a temperature compensated crystal oscillator (comparative sample C1) of the related art. Accordingly, for example, the oscillator 1 is used for a communication apparatus and the like as described later, and thus it is possible to realize the communication apparatus having excellent communication performance even under a severe temperature environment. In addition, for example, it is also possible to apply the oscillator 1 to an electronic apparatus or a vehicle using an oven controlled crystal oscillator (OCXO) and requiring high frequency stability. As a result, it is possible to reduce the size and power consumption of the electronic apparatus or the vehicle.

In the oscillator 1, the integrated circuit (IC) 2 is bonded to the base 4a of the package 4. For this reason, in the oscillator 1, heat generated by the integrated circuit (IC) 2 is transmitted to the resonator 3 in a short period of time, and thus a difference in temperature between the integrated circuit (IC) 2 and the resonator 3 is reduced. As a result, in the oscillator 1, an error of temperature compensation due to the temperature compensation circuit 40 is decreased, and thus it is possible to realize the above-described excellent wander performance.

In the oscillator 1, the lid 4b of the package 4 is bonded to the base 8a of the package 8. For this reason, in the oscillator 1, the integrated circuit (IC) 2 can be bonded to the second surface 15b of the base 4a, and thus it is possible to reduce a difference in temperature between the integrated circuit (IC) 2 and the resonator 3 as described above.

In the oscillator 1, the resonator 3 is positioned between the lid 4b of the package 4 and the lid 8b of the package 8. For this reason, in the oscillator 1, for example, the lid 4b and the lid 8b are formed of a metal, and thus it is possible to cause the lid 4b and the lid 8b to function as shields for shielding noise (electromagnetic noise) from the outside and to reduce the influence of noise to the resonator 3.

In the oscillator 1, the second surface 15b of the base 4a is provided with the external terminals 5a and 5b which are electrically connected to the resonator 3. For this reason, in the oscillator 1, the external terminals 5a and 5b can be separated from the bottom surface of the recessed portion of the package 8, and thus it is possible to reduce the influence of noise from the outside. Further, in the oscillator 1, the second surface 15b of the base 4a is provided with the external terminals 5a and 5b, and thus it is possible to reduce the length of a wiring between the resonator 3 and the integrated circuit (IC) 2 and to reduce the influence of noise. For example, in a case where the resonator 3 and the integrated circuit (IC) 2 are electrically connected to each other through a wiring provided inside the base 8a of the package 8 or on the surface of the recessed portion, the length of the wiring is increased, and thus the influence of noise is easily exerted.

### 1.4. Modification Example of Oscillator

Next, a modification example of the oscillator according to this exemplary embodiment will be described.

### (1) First Modification Example

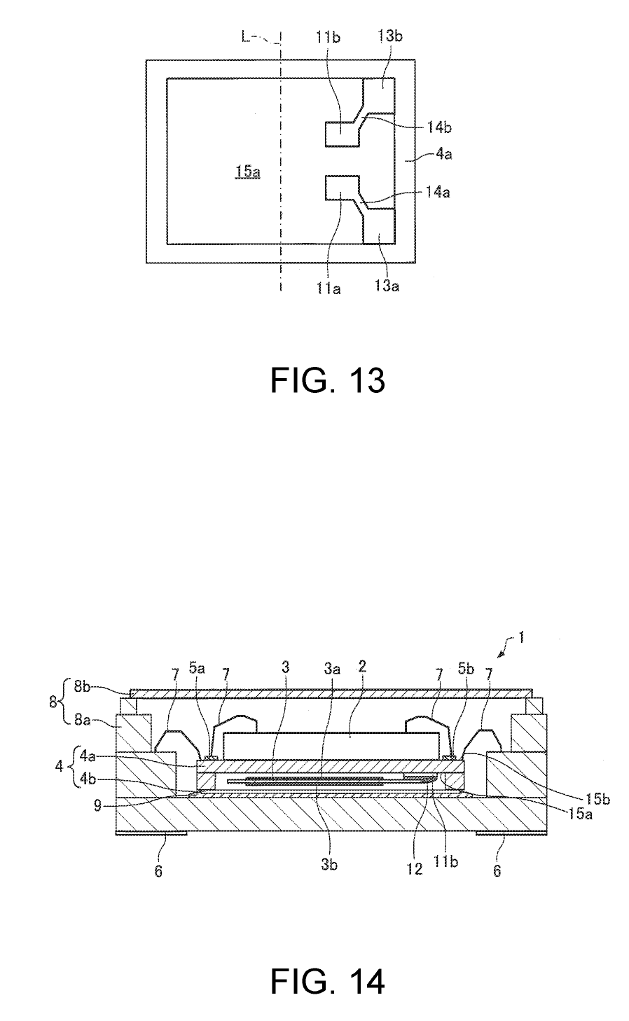

FIG. 13 is a schematic plan view showing a base 4a of a package 4 of an oscillator according to a first modification example. FIG. 13 corresponds to FIG. 5.

In the oscillator according to the first modification example, as illustrated in FIG. 13, the arrangement of electrode pads 11a and 11b, electrode pads 13a and 13b, and leading wirings 14a and 14b which are provided on the base 4a is different from the above-described arrangement illustrated in FIG. 5. Hereinafter, this difference will be described, and the same respects will not be described.

As illustrated in FIG. 13, when the base 4a is divided into two equal parts by drawing a virtual straight line L passing through the center of the base 4a when seen in a plan view, the electrode pad 13a and the electrode pad 13b are positioned on a side where the electrode pad 11a and the electrode pad 11b are provided. For this reason, as compared to the arrangement illustrated in FIG. 5, it is possible to reduce a difference between the length of the leading wiring 14a and the length of the leading wiring 14b. In the example shown in the drawing, the length of the leading wiring 14a and the length of the leading wiring 14b are equal to each other.

In the oscillator according to the first modification example, when the base 4a is divided into two equal parts by drawing the virtual straight line L passing through the center of the base 4a when seen in a plan view, the electrode pad 13a and the electrode pad 13b are positioned on a side where the electrode pad 11a and the electrode pad 11b are provided. For this reason, it is possible to reduce a difference between the length of the leading wiring 14a and the length of the leading wiring 14b. Thereby, it is possible to reduce a difference between a path length of a path through which heat from the outside of the package 4 is transmitted to a resonator 3 through the electrode pad 13a, the leading wiring 14a, and the electrode pad 11a and a path length of a path through which heat is transmitted to the resonator 3 through the electrode pad 13b, the leading wiring 14b, and the electrode pad 11b.

As a result, for example, as compared to the above-described example of the oscillator 1 illustrated in FIG. 5, it is possible to reduce temperature unevenness of the resonator 3 and to further reduce a difference in temperature between the integrated circuit (IC) 2 and the resonator 3. Therefore, according to the first modification example, it is possible to realize the oscillator having more excellent wander performance than the above-described wander performance of the oscillator 1 illustrated in FIGS. 11 and 12.

### (2) Second Modification Example

In the above-described exemplary embodiment, a space for accommodating the resonator 3 of the package 4 and a space for accommodating the integrated circuit (IC) 2 of the package 8 and the package 4 are nitrogen gas atmospheres, but these spaces may be helium gas atmospheres. Since a helium gas has higher thermal conductivity than that of a nitrogen gas, it is possible to further reduce a difference in temperature between the integrated circuit (IC) 2 and the resonator 3. As a result, according to this modification example, it is possible to realize the oscillator having more excellent wander performance than the above-described wander performance of the oscillator 1 illustrated in FIGS. 11 and 12.

In addition, a space for accommodating the resonator 3 of the package 4 may be an inert gas atmosphere such as a nitrogen gas or a helium gas, and a space (space for accommodating the integrated circuit (IC) 2 and the package 4) within the package 8 may be a vacuum (state where pressure is lower than atmospheric pressure). Thereby, it is possible to reduce the influence of a temperature fluctuation outside the package 8 on the integrated circuit (IC) 2 and the resonator 3 while reducing a difference in temperature between the integrated circuit (IC) 2 and the resonator 3. As a result, according to this modification example, it is possible to realize the oscillator having more excellent wander performance than the above-described wander performance of the oscillator 1 illustrated in FIGS. 11 and 12.

### (3) Third Modification Example

FIG. 14 is a schematic cross-sectional view showing an oscillator 1 according to a third modification example. FIG. 14 corresponds to FIG. 2.

The oscillator according to the third modification example is different from the above-described oscillator illustrated in FIG. 2 in that the external terminals 5a and 5b provided on the second surface 15b of the base 4a and the terminals of the integrated circuit (IC) 2 are connected to each other through the bonding wires 7 as illustrated in FIG. 14. Hereinafter, this difference will be described, and the same respects will not be described.

As illustrated in FIG. 14, even when the external terminals 5a and 5b and the terminals of the integrated circuit (IC) 2 are connected to each other through the bonding wires 7, it is possible to reduce the length of the wiring between the resonator 3 and the integrated circuit (IC) 2, similar to the above-described example illustrated in FIG. 2.

Meanwhile, in the example illustrated in FIG. 2, each terminal of the integrated circuit (IC) 2 and the wiring (wiring electrically connected to each external terminal 6) which is provided in the base 8a are directly bonded to each other through the bonding wire 7. On the other hand, in the example illustrated in FIG. 14, each terminal of the integrated circuit (IC) 2 and the wiring provided in the base 8a are connected to each other through a wiring, not shown in the drawing, which is provided on the second surface 15b of the base 4a. Specifically, the second surface 15b of the base 4a is provided with the wiring connected to each terminal of the integrated circuit (IC) 2, and the wiring is connected to the wiring provided in the base 8a through the bonding wire 7.

According to this modification example, it is possible to exhibit the same operational effects as those of the above-described oscillator 1 illustrated in FIG. 2.

### 2. Electronic Apparatus

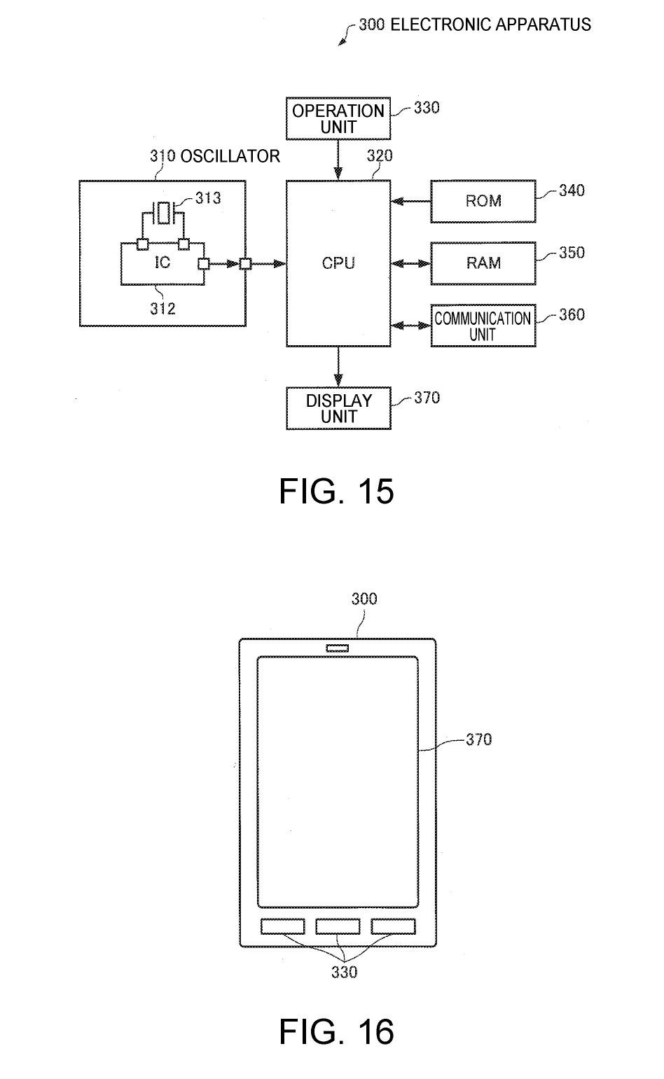

FIG. 15 is a functional block diagram showing an example of a configuration of an electronic apparatus according to this exemplary embodiment. In addition, FIG. 16 is a diagram showing an example of the appearance of a smart phone as an example of the electronic apparatus according to this exemplary embodiment.

An electronic apparatus 300 according to this exemplary embodiment is configured to include an oscillator 310, a Central Processing Unit (CPU) 320, an operation unit 330, a Read Only Memory (ROM) 340, a Random Access Memory (RAM) 350, a communication unit 360, and a display unit 370. Meanwhile, the electronic apparatus according to this exemplary embodiment may be configured such that a portion of the components (units) of FIG. 15 is omitted or changed or other components are added.

The oscillator 310 includes an integrated circuit (IC) 312 and a vibrator 313. The integrated circuit (IC) 312 oscillates the vibrator 313 to generate an oscillation signal. The oscillation signal is output to the CPU 320 from an external terminal of the oscillator 310.

The CPU 320 performs various types of calculation processes and control processes using the oscillation signal which is input from the oscillator 310 as a clock signal, in accordance with a program stored in the ROM 340 or the like. Specifically, the CPU 320 performs various types of processes in response to an operation signal from the operation unit 330, a process of controlling the communication unit 360 in order to perform data communication with the external device, a process of transmitting a display signal for causing the display unit 370 to display various pieces of information, and the like.

The operation unit 330 is an input device constituted by operation keys, button switches or the like, and outputs an operation signal in response to a user's operation to the CPU 320.

The ROM 340 stores programs, data, or the like for causing the CPU 320 to perform various types of calculation processes and control processes.

The RAM 350 is used as a work area of the CPU 320, and temporarily stores programs and data which are read out from the ROM 340, data which is input from the operation unit 330, computation results executed by the CPU 320 in accordance with various types of programs, and the like.

The communication unit 360 performs a variety of control for establishing data communication between the CPU 320 and an external device.

The display unit 370 is a display device constituted by a liquid crystal display (LCD) or the like, and displays various pieces of information on the basis of a display signal which is input from the CPU 320. The display unit 370 may be provided with a touch panel functioning as the operation unit 330.

For example, the above-described oscillator 1 is applied as the oscillator 310, and thus it is possible to realize the electronic apparatus including the oscillator having excellent wander performance even under a severe temperature environment.

As the electronic apparatus 300, various electronic apparatuses are considered. For example, the electronic apparatus includes a personal computer (for example, mobile-type personal computer, laptop personal computer, or tablet personal computer), a smart phone, a mobile terminal such as a cellular phone, a digital still camera, an ink jet ejecting device (for example, ink jet printer), a storage area network apparatus such as a router or a switch, a local area network apparatus, an apparatus for a mobile terminal base station, a television, a video camera, a video recorder, a car navigation device, a real-time clock device, a pager, an electronic notebook (also including a communication function), an electronic dictionary, an electronic calculator, an electronic game console, a game controller, a word processor, a workstation, a TV phone, a security TV monitor, electronic binoculars, a POS terminal, a medical instrument (for example, electronic thermometer, sphygmomanometer, blood glucose monitoring system, electrocardiogram measurement device, ultrasound diagnostic device, and electronic endoscope), a fish detector, various types of measuring apparatus, meters and gauges (for example, meters and gauges of a vehicle, an aircraft, and a vessel), a flight simulator, a head mounted display, a motion tracer, a motion tracker, a motion controller, PDR (walker position and direction measurement), and the like.

Examples of the electronic apparatus 300 according to this exemplary embodiment include a transmission device functioning as a device for terminal base station that communicates with a terminal in a wired or wireless manner by using the above-described oscillator 310 as a reference signal source, a voltage variable oscillator (VCO), or the like. The oscillator 1 is applied as the oscillator 310, and thus it is possible to realize the electronic apparatus which is usable for, for example, a communication base station or the like and requires high performance and high reliability.

In addition, another example of the electronic apparatus 300 according to this exemplary embodiment may be a communication device in which the communication unit 360 receives an external clock signal, and the CPU 320 (processing unit) includes a frequency control unit that controls the frequency of the oscillator 310 on the basis of the external clock signal and an output signal (internal clock signal) of the oscillator 310. The communication device may be a communication apparatus which is used in abase system network apparatus, such as a stratum 3, or a femtocell.

### 3. Vehicle

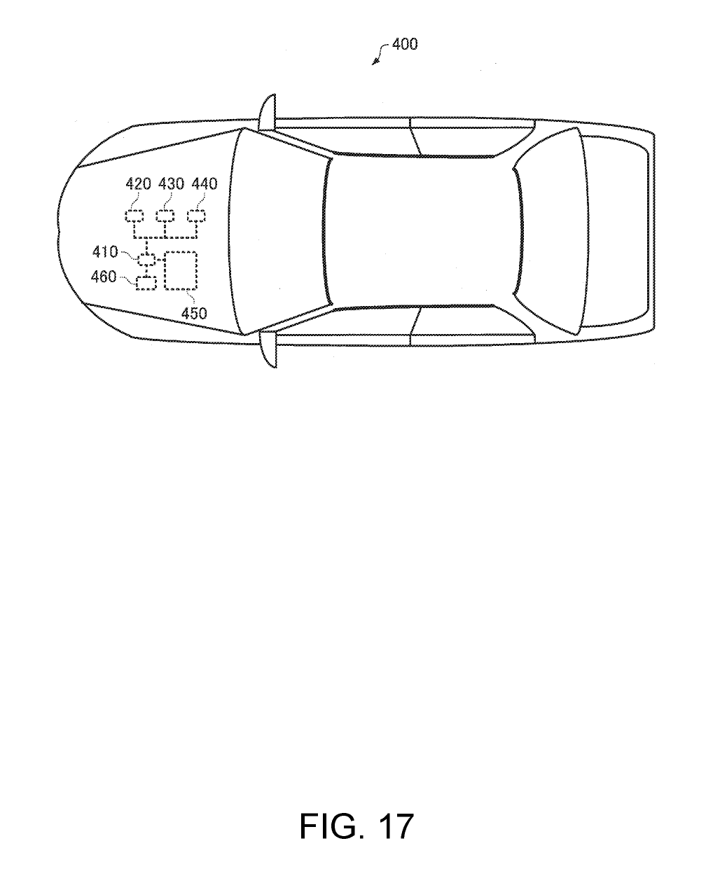

FIG. 17 is a diagram (top view) showing an example of the vehicle according to this exemplary embodiment. The vehicle 400 shown in FIG. 17 is configured to include an oscillator 410, controllers 420, 430, and 440 that perform a variety of control of an engine system, a brake system, a keyless entry system and the like, a battery 450, and a backup battery 460. Meanwhile, the vehicle according to this exemplary embodiment may be configured such that a portion of the components (units) of FIG. 17 is omitted or changed or other components are added.

The oscillator 410 includes an integrated circuit (IC) and a resonator which are not shown in the drawing, and the integrated circuit (IC) oscillates the resonator to generate an oscillation signal. The oscillation signal is output to the controllers 420, 430, and 440 from an external terminal of the oscillator 410, and is used as, for example, a clock signal.

The battery 450 supplies power to the oscillator 410 and the controllers 420, 430, and 440. The backup battery 460 supplies power to the oscillator 410 and the controllers 420, 430, and 440 when an output voltage of the battery 450 is lower than a threshold value.

For example, the above-described oscillator 1 is applied as the oscillator 410, and thus it is possible to realize the vehicle including the oscillator having excellent wander performance even under a severe temperature environment.

Various mobile bodies are considered as such a vehicle 400. The vehicle includes, for example, an automobile (also including an electric automobile), an aircraft such as a jet engine airplane or a helicopter, a vessel, a rocket, a satellite, and the like.

The above-described exemplary embodiment and modification examples are merely examples, and the invention is not limited thereto. For example, the exemplary embodiment and the modification examples can also be appropriately combined with each other.

The invention includes configurations (for example, configurations having the same functions, methods and results, or configurations having the same objects and effects) which are substantially the same as the configurations described in the above exemplary embodiments. In addition, the invention includes configurations in which non-essential elements of the configurations described in the exemplary embodiments are replaced. In addition, the invention includes configurations exhibiting the same operations and effects as, or configurations capable of achieving the same objects as, the configurations described in the exemplary embodiments. In addition, the invention includes configurations in which known techniques are added to the configurations described in the exemplary embodiments.

The entire disclosure of Japanese Patent Application No. 2017-003185, filed Jan. 12, 2017 is expressly incorporated by reference herein.

What is claimed is:

1. An oscillator which is a temperature compensated oscillator, the oscillator comprising:
a resonator;
a first case that includes a base and a lid and accommodates the resonator;
an electronic component that includes an oscillation circuit and a temperature compensation circuit; and
a second case that accommodates the first case and the electronic component,
wherein the electronic component is bonded to the base of the first case, and
wherein in a case where a temperature range of ±5° C. is changed with a cycle of six minutes on the basis of a reference temperature, wander performance satisfies a condition that an MTIE value of 0 s<τ≤0.1 s is equal to or less than 6 ns, an MTIE value of 0.1 s<τ≤1 s is equal to or less than 27 ns, an MTIE value of 1 s<τ≤10 s is equal to or less than 250 ns, an MTIE value of 10 s<τ≤100 s is equal to or less than 1700 ns, and an MTIE value of 100 s<τ≤1000 s is equal to or less than 6332 ns when an observation time is set to τ.

2. The oscillator according to claim 1,
wherein in a case where a temperature is maintained constant at the reference temperature, the wander performance satisfies a condition that an MTIE value of 0.1 s<τ≤1 s is equal to or less than 15 ns, an MTIE value of 1 s<τ≤10 s is equal to or less than 23 ns, an MTIE value of 10 s<τ≤100 s is equal to or less than 100 ns, and an MTIE value of 100 s<τ≤1000 s is equal to or less than 700 ns.

3. The oscillator according to claim 1,
wherein the lid of the first case is bonded to the second case.

4. The oscillator according to claim 1,
wherein the second case includes a base and a lid, and
wherein the resonator is positioned between the lid of the first case and the lid of the second case.

5. The oscillator according to claim 1,
wherein a terminal electrically connected to the resonator is provided on a surface of the base of the first case which is bonded to the electronic component.

6. The oscillator according to claim 1,
wherein a space in the second case is a vacuum.

7. An oscillator which is a temperature compensated oscillator, the oscillator comprising:
a resonator;
a first case that includes a base and a lid and accommodates the resonator;
an electronic component that includes an oscillation circuit and a temperature compensation circuit; and
a second case that accommodates the first case and the electronic component,
wherein the electronic component is bonded to the base of the first case, and
wherein in a case where a temperature is maintained constant at a reference temperature, wander performance satisfies a condition that an MTIE value of 0.1 s<τ≤1 s is equal to or less than 15 ns, an MTIE value of 1 s<τ≤10 s is equal to or less than 23 ns, an MTIE value of 10 s<τ≤100 s is equal to or less than 100 ns, and an MTIE value of 100 s<τ≤1000 s is equal to or less than 700 ns.

8. An electronic apparatus comprising the oscillator according to claim 1.

9. An electronic apparatus comprising the oscillator according to claim 2.

10. An electronic apparatus comprising the oscillator according to claim 3.

11. An electronic apparatus comprising the oscillator according to claim 4.

12. An electronic apparatus comprising the oscillator according to claim 5.

13. An electronic apparatus comprising the oscillator according to claim 6.

14. An electronic apparatus comprising the oscillator according to claim 7.

15. A vehicle comprising the oscillator according to claim 1.

16. A vehicle comprising the oscillator according to claim 2.

17. A vehicle comprising the oscillator according to claim 3.

18. A vehicle comprising the oscillator according to claim 4.

19. A vehicle comprising the oscillator according to claim 5.

20. A vehicle comprising the oscillator according to claim 6.
